(19) United States
(12) Patent Application Publication
(10) Pub. No.: US 2010/0201417 A1
(43) Pub. Date: Aug. 12, 2010

(54) Clock extraction circuit

(75) Inventor: Yasushi Wakayama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/656,401

(22) Filed: Jan. 28, 2010

(30) Foreign Application Priority Data
Feb. 6, 2009 (JP) 2009-026190

(51) Int. Cl. H03L 7/00

(52) U.S. Cl. 327/161

(57) ABSTRACT

Error occurrence is predicted before the error occurs. Included are: a clock regeneration circuit (11) that regenerates, from a data input signal (Din), a clock signal (CK1) related to the data input signal (Din); a sampling clock generation circuit (12) that generates one or more sampling clock signals (CK2 and CK3) that are synchronous with the regenerated signal (CK1) and have a constant phase difference with respect to the regenerated clock signal (CK1); a sample and hold circuit (13) that samples and holds the data input signal (Din) according to the one or more sampling clock signals (CK2 and CK3) and the regenerated clock signal (CK1) respectively; and an error determination circuit (14) that outputs an error prediction signal (Ep) in a case where logical values of respective sampling results of the sample and hold circuit (13) are not all identical.

### TECHNICAL FIELD

### Reference to Related Application

This application is based upon and claims the benefit of the priority of Japanese patent application No. 2009-026190, filed on Feb. 6, 2009, the disclosure of which is incorporated herein in its entirety by reference thereto.

The present invention relates to a clock extraction circuit, and in particular to a clock extraction circuit that receives a data signal only, and extracts a clock signal from that data signal to perform retiming.

### BACKGROUND

In order to reduce the number of cables when performing communication by cable, for example, and reduce cost, a clock extraction circuit is used for transmitting a data signal only on a transmission side, and for extracting a clock signal from the data signal on a reception side, to perform retiming. Clock extraction circuits have been mainly used in long distance communication heretofore. However, in recent years various types of interface have been speeded up so that realization of parallel interfaces that simultaneously transmit clock signals and data signals has become difficult, and examples where clock extraction circuits are used as substitutes for these have increased. For example, a PCI-Express or the like, used as an interface mainly for personal computers, with the assumption of usage of a clock recovery circuit, is an interface for transmitting data signals only.

With regard to this clock extraction circuit, usage of a PLL (phase locked loop) circuit, a phase interpolator circuit, or the like is known for generating multi-phase clock signals (refer to Non-Patent Document 1). Furthermore, a system is known in which, when selecting an optimal phase, a clock position at which an error does not occur is selected while switching the phase (refer to Patent Document 1).

### [Patent Document 1]

Japanese Patent Kohyo Publication No. JP-P2002-523971A

### [Non-Patent Document 1]

Muneo Fukaishi et al., “A 20-Gb/s CMOS Multichannel Transmitter and Receiver Chip Set for Ultra-High-Resolution Digital Displays”, IEEE Journal of Solid-State Circuits, Volume 35, No 11, pp. 1611-1618, November 2000.

### SUMMARY

The entire disclosures of Patent Document 1 and Non-Patent Document 1 are incorporated herein by reference thereto.

The following analysis is given by the present invention.

In recent years, as situations where clock extraction circuits are used occur more frequently, there are cases of usage in systems in which errors basically must not occur, rather than systems assuming error generation to a certain extent as in long distance communication. In a system assuming that an error occurs, such as in long distance communication and the like, error correction by an error correction circuit or a procedure for re-sending data when an error occurs is applied, and the system is adapted to tolerate errors to a certain extent.

However, in systems where this type of circuit or procedure is not implemented, problems may occur when the system stops or the like due to error occurrence. When these systems are operated for a long time, there is a reduction in time duration (open ratio) in which retiming is possible, accompanying peripheral circuit deterioration, noise environment change and the like. In such cases, it is not possible to notice a decrease in this time duration until an error has occurred, nor is it possible to take measures such as replacing a part that has deteriorated, before the error occurrence.

According to one aspect of the present invention, a clock extraction circuit is provided with: a clock regeneration circuit that regenerates, from a data input signal, a clock signal related to the data input signal; a sampling clock generation circuit that generates one or more sampling clock signals that are synchronous with the regenerated clock signal and have a constant phase difference with respect to the regenerated clock signal; a sample and hold circuit that samples and holds the data input signal according to the one or more sampling clock signals and the regenerated clock signal respectively; and an error determination circuit that outputs an error prediction signal in a case where logical values of respective sampling results of the sample and hold circuit are not all in agreement.

The meritorious effects of the present invention are summarized as follows.

According to the present invention, it is possible to predict an error occurrence before the error occurs. Therefore, it is possible to take measures such as replacing a part that has deteriorated, before the error occurs.

### BRIEF DESCRIPTION OF THE DRAWINGS

FIG. 1 is a block diagram showing a configuration of a clock extraction circuit according to a first exemplary embodiment of the present invention.

FIG. 2 is a timing chart representing operation of the clock extraction circuit according to the first exemplary embodiment of the present invention.

FIG. 3 is a block diagram showing a configuration of the clock extraction circuit according to a second exemplary embodiment of the present invention.

FIG. 4 is a timing chart representing operation of the clock extraction circuit according to the second exemplary embodiment of the present invention.

### PREFERRED MODES

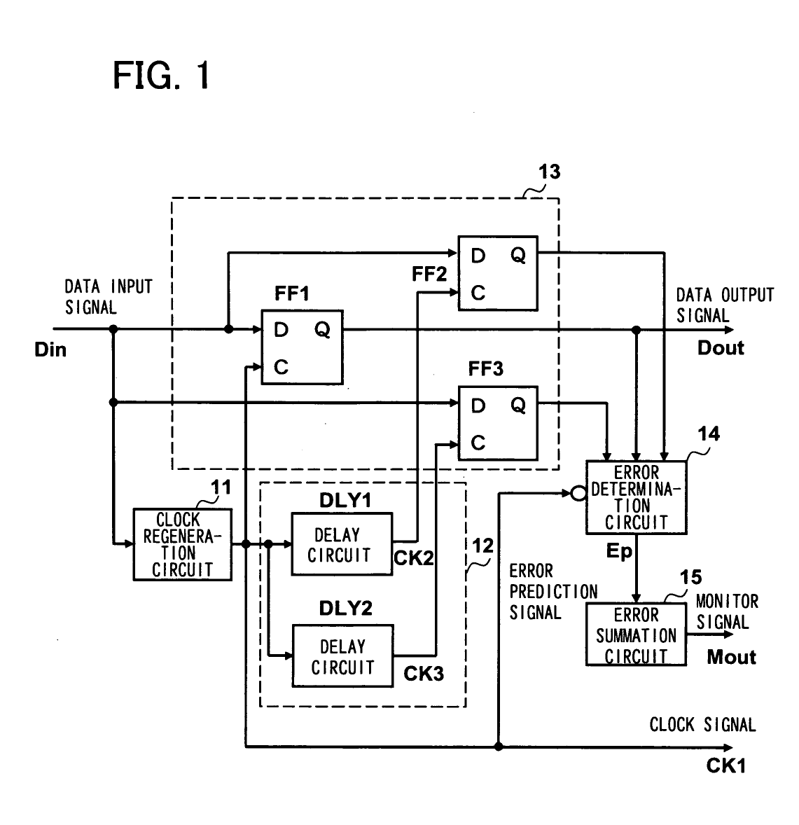

A clock extraction circuit according to an embodiment of the present invention is provided with: a clock regeneration circuit (11 in FIG. 1) that regenerates, from a data input signal (Din in FIG. 1), a clock signal (CK1 in FIG. 1) related to the data input signal, a sampling clock generation circuit (12 in FIG. 1) that generates one or more sampling clock signals (CK2 and CK3 in FIG. 1) that are synchronous with the regenerated clock signal and have a constant phase difference with respect to the regenerated clock signal, a sample and hold circuit (13 in FIG. 1) that samples and holds the data input signal according to the one or more sampling clock signals and the regenerated clock signal respectively, and an error determination circuit (14 in FIG. 1) that outputs an error prediction signal (Ep in FIG. 1) in a case where logical values of respective sampling results of the sample and hold circuit are not all in agreement.

The sampling clock generation circuit may be provided with delay circuits (DLY1 and DLY2 of FIG. 1) that give a fixed delay to the regenerated clock signal, and output sampling clock signals.

The clock regeneration circuit may generate N-phase clock signals including, as a K-th phase clock signal, the regenerated clock signal (K is an integer such that 1≦K≦N, and N is an integer such that 1<N); and the sampling clock generation circuit may select a (K+M)-th phase and/or a (K−M)-th phase clock signal (M is an integer such that 1≦M≦K−1, with K+M≦N, and 0<K−M) from among the N-phase clock signals generated by the clock regeneration circuit, to have the sampling clock signals.

An error summation circuit (15 in FIG. 1) that sums up error prediction signals in a time-wise manner may additionally be provided.

The sampling clock generation circuit (13) may comprise first and second delay circuits (DLY1, DLY2), one of which gives a first fixed delay to the generated first clock signal for outputting a first delayed clock signal, and the other of which gives a second fixed delay to the generated first clock signal so as to output a second delayed clock signal having an advanced phase relative to the generated first clock signal.

The clock regeneration circuit may be a multiple-phase clock generation circuit (16) that generates, from the data input signal, multiple-phase clock signals; and the sampling clock generation circuit comprises first and second clock selection circuits (SEL1, SEL2), one of which selects and outputs a first delay clock signal having a first fixed delay to the generated first clock signal, and the other of which selects and outputs a second delay clock signal having a second fixed delay to the generated first clock signal so as to provide an advanced signal thereto.

According to the above type of clock extraction circuit, an error prediction signal can be outputted before an error occurs, and it is possible to predict an error occurrence. Therefore, it is possible to take measures such as replacing a part that has deteriorated, before an error occurs.

A detailed description is given below according to exemplary embodiments, making reference to the drawings.

### First Exemplary Embodiment

FIG. 1 is a block diagram showing a configuration of a clock extraction circuit according to a first exemplary embodiment of the present invention. In FIG. 1, the clock extraction circuit is provided with a clock regeneration circuit 11, a sampling clock generation circuit 12, a sample and hold circuit 13, an error determination circuit 14, and an error adding circuit 15. The sampling clock generation circuit 12 is provided with delay circuits DLY1 and DLY2. Furthermore, the sample and hold circuit 13 is provided with D-type flip-flop circuits FF1 to FF3.

The clock regeneration circuit 11 regenerates, from a data input signal Din, a clock signal CK1 related to the data input signal Din, to be outputted to a clock terminal (C) of the flip-flop circuit FF1. The delay circuit DLY1 delays the clock signal CK1, and generates a clock signal CK2 whose phase is delayed according to a prescribed fixed delay, to be outputted to a clock terminal (C) of the flip-flop circuit FF2. The delay circuit DLY2 delays the clock signal CK1, and generates a clock signal CK3 whose phase is advanced according to the prescribed fixed delay, to be outputted to a clock terminal (C) of the flip-flop circuit FF3. Since the clock signal CK3 whose phase is advanced cannot be generated in just a fixed delay circuit, this is realized equivalently by using a delay circuit having a delay exceeding one cycle with regard to the clock signal CK1.

The flip-flop circuit FF1 latches the data input signal Din at a rising edge of the clock signal CK1, and outputs to the outside and to the error determination circuit 14 as a data output signal Dout. The flip-flop circuits FF2 and FF3 latch the data input signal Din at rising edges of the clock signals CK2 and CK3, respectively, and output to the error determination circuit 14.

In a case where all logical values of output (Q) of the flip-flops FF1 to FF3 are not in agreement, the error determination circuit 14 outputs an error prediction signal Ep to the error adding circuit 15. The error determination circuit 14 can make a determination at the same time as performing retiming of 3 items of data for the determination at a falling edge of the clock signal CK1. The error adding circuit 15 sums up the error prediction signals Ep in a time-wise manner, and outputs summation result to the outside as a monitor signal Mout. That is, in a case where the error prediction signals Ep are outputted not in transitory fashion but continuously, the monitor signal Mout is outputted for giving a direction to replace a deteriorated part, or the like.

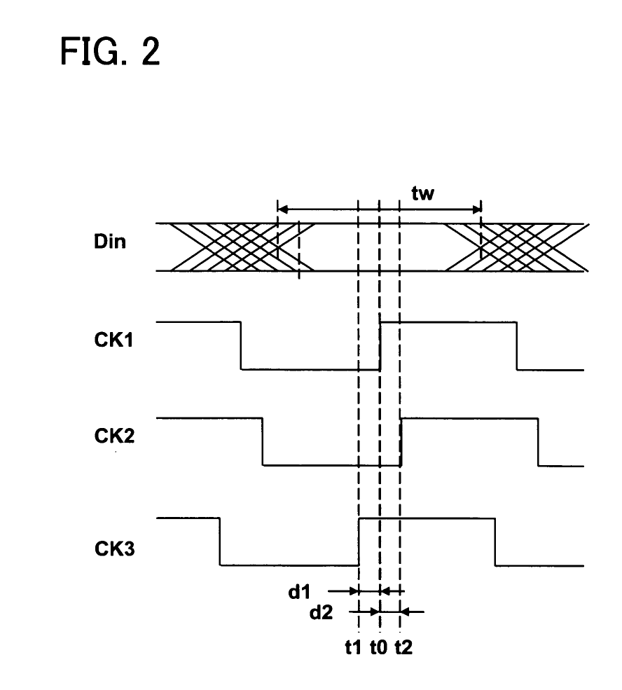

Next, operation of the clock extraction circuit is described. FIG. 2 is a timing chart representing operation of the clock extraction circuit according to the first exemplary embodiment of the present invention. As shown in FIG. 2, a clock signal CLK1 that is optimal for retiming is generated from the data input signal Din for use in retiming. In addition, with regard to the clock signal CLK1, the clock signal CK3 whose phase is advanced by time d1 only, and the clock signal CK2 whose phase is delayed by time d2 only are generated. In general, d1=d2.

Normally, when there is an occurrence of an error accompanying peripheral circuit deterioration, noise environment change, or the like, for example, the width of the input data signal Din gradually increases with degree of deterioration, and retiming area tw corresponding to open ratio gradually narrows. Finally, when the deterioration progresses to such an extent that this area disappears, and/or a large amount of noise is added, an error occurs. Here, a method of error prediction is used by determining agreement or disagreement between data that have undergone retiming (timing t1, t2) according to clock signals CK3 and CK2, and data that have undergone retiming (timing t0) by the clock signal CK1 at optimal phase.

That is, in a case where the retiming area tw gradually narrows, first, data that have undergone retiming according to the clock signals CK3 and CK2 cause an error. After data that have undergone retiming by the clock signal CK1 pass through a state in which an error does not occur, finally an error occurs also in the data that have undergone retiming by the clock signal CK1. That is, while the data that have undergone retiming according to the clock signals CK3 and CK2 cause an error, in a state where an error does not occur in data that have undergone retiming by the clock signal CK1, that is, in a case where data that have undergone retiming by clock signals CK1, and CK2, and CK3 are not all the same, it is possible to predict an error by generation of the error prediction signal Ep.

### Second Exemplary Embodiment

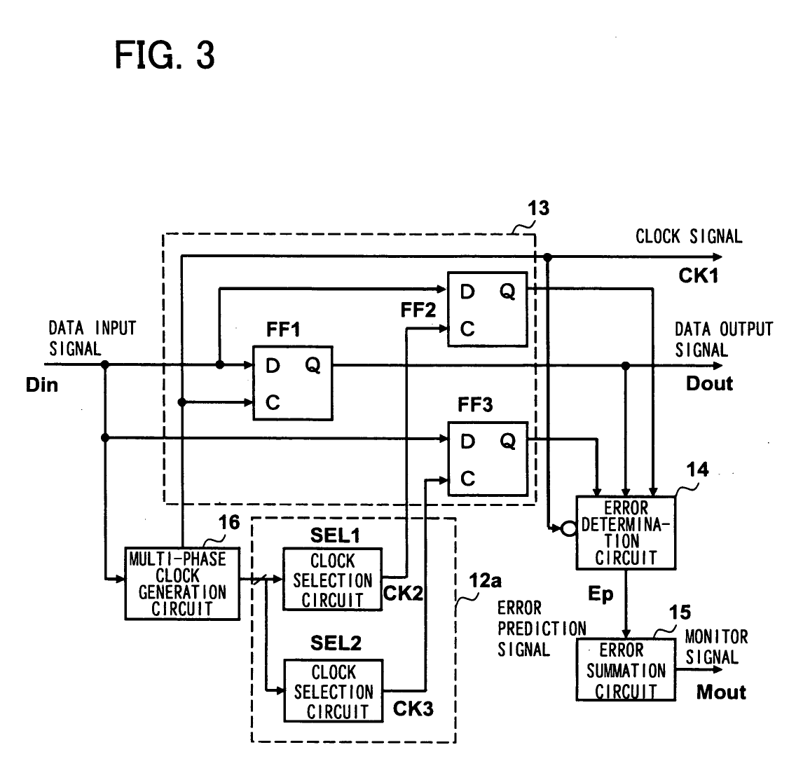

FIG. 3 is a block diagram showing a configuration of a clock extraction circuit according to a second exemplary embodiment of the present invention. In FIG. 3, reference symbols the same as in FIG. 1 represent the same items, and descriptions thereof are omitted. The clock extraction circuit of the present exemplary embodiment is provided with a multi-phase clock generation circuit 16 and a sampling clock generation circuit 12a instead of the clock generation circuit 11 and the sampling clock generation circuit 12, respectively.

The multi-phase clock generation circuit 16 uses a PLL (phase locked loop) circuit, a phase interpolator circuit, and the like, to generate N clock signals having phases obtained by dividing one data cycle of the data input signal Din into N portions. That is, an N-phase clock signal, including a clock signal CK1 as a K-th phase clock signal (K is an integer such that 1≦K≦N, and N is an integer such that 1<N), is generated.

The sampling clock generation circuit 12a is provided with clock selection circuits SEL1 and SEL2. The clock selection circuit SEL1 selects a (K+M)-th phase clock signal from among N-phase clock signals; that is, a clock signal having a prescribed phase delayed with respect to the clock signal CK1 is selected, and is outputted as a clock signal CK2 to a clock terminal (C) of a flip-flop circuit FF2. Furthermore, a clock selection circuit SEL2 selects a (K−M)-th phase clock signal from among the N-phase clock signals; that is, a clock signal having a prescribed phase advanced with respect to the clock signal CK1 is selected, and is outputted as a clock signal CK3 to a clock terminal (C) of a flip-flop circuit FF3.

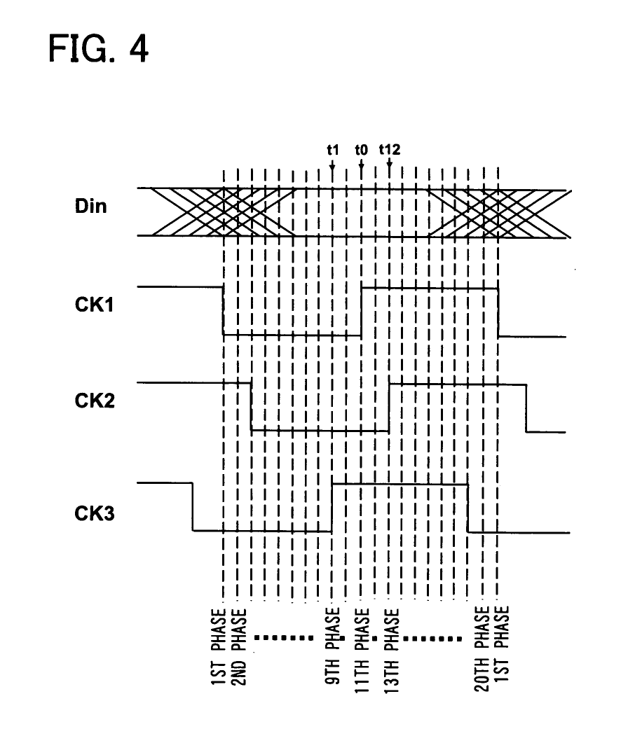

Next, operation of the clock extraction circuit is described. FIG. 4 is a timing chart representing operation of the clock extraction circuit according to the second exemplary embodiment of the present invention. In the example shown in FIG. 4, the multi-phase clock generation circuit 16 outputs a multi-phase clock signal of N-phases (N=20). A K-th (K=11) phase clock signal is taken as the clock signal CLK1 that is of an optimum phase, a 13-th phase clock signal having an M-phase delay (M=2) with respect to the clock signal CLK1 is taken as the clock signal CK2, and a 9-th phase clock signal having an M-phase advance (M=2) with respect to the clock signal CLK1 is taken as the clock signal CK3.

Similarly to the clock extraction circuit of the first exemplary embodiment, in a case where data that have undergone retiming by the clock signals CK1, CK2, and CK3 are not all the same, this type of clock extraction circuit can predict an error by generating an error prediction signal Ep.

In the descriptions of the abovementioned first and second exemplary embodiments, retiming according to the clock signals CK3 and CK2 has been described. However, normally, since the retiming area tw is symmetrical to the left and right with respect to a rising edge of the clock signal CK1, it is possible to predict an error even with retiming of only one of either of the clock signals CK3 and CK2.

The various disclosures of the abovementioned patent documents and the like are incorporated herein by reference thereto. Modifications and adjustments of embodiments and examples are possible within the bounds of the entire disclosure (including the scope of the claims) of the present invention, and also based on fundamental technological concepts thereof. Furthermore, a wide variety of combinations and selections of various disclosed elements are possible within the scope of the claims of the present invention. That is, the present invention clearly includes every type of transformation and modification that a person skilled in the art can realize according to technological concepts and the entire disclosure including the scope of the claims.

What is claimed is:

1. A clock extraction circuit comprising:
a clock regeneration circuit that regenerates, from a data input signal, a first clock signal related to said data input signal;
a sampling clock generation circuit that generates at least one sampling clock signal that is synchronous with said regenerated clock signal and has a constant phase difference with respect to said regenerated first clock signal;
a sample and hold circuit that samples and holds said data input signal according to said at least one sampling clock signal and said regenerated first clock signal respectively; and
an error determination circuit that outputs an error prediction signal in a case where logical values of respective sampling results of said sample and hold circuit are not all identical.

2. The clock extraction circuit according to claim 1, wherein said sampling clock generation circuit comprises: a delay circuit that gives a fixed delay to said regenerated first clock signal and outputs said at least one sampling clock signal.

3. The clock extraction circuit according to claim 1, wherein
said clock regeneration circuit generates N-phase clock signals including, as a K-th phase clock signal, said regenerated clock signal (K is an integer such that 1≦K≦N, and N is an integer such that 1<N); and
said sampling clock generation circuit selects at least one of a (K+M)-th phase and a (K−M)-th phase clock signal (M is an integer such that 1≦M≦K−1, with K+M≦N, and 0<K−M) from among said N-phase clock signals generated by said clock regeneration circuit, to have said at least one sampling clock signal.

4. The clock extraction circuit according to claim 1, further comprising an error summation circuit that sums up said error prediction signal in a time-wise manner.

5. The clock extraction circuit according to claim 1, wherein
said sampling clock generation circuit comprises a pair of first and second delay circuits, one of which gives a first fixed delay to said generated first clock signal for outputting a first delayed clock signal, and the other of which gives a second fixed delay to said generated first clock signal so as to output a second delayed clock signal having an advanced phase relative to said generated first clock signal.

6. The clock extraction circuit according to claim 1, wherein
said clock regeneration circuit is a multiple-phase clock generation circuit that generates, from the data input signal, multiple-phase clock signals; and
said sampling clock generation circuit comprises first and second clock selection circuits, one of which selects and outputs a first delay clock signal having a first fixed delay to said generated first clock signal; and the other of which selects and outputs a second delay clock signal having a second fixed delay to said generated first clock signal so as to provide an advanced signal thereto.
